(19) United States
(12) Patent Application Publication
(10) Pub. No.: US 2016/0087591 A1
(43) Pub. Date: Mar. 24, 2016

(54) METHODS AND SYSTEMS FOR EFFICIENT AND ADAPTIVE OPERATION OF CONTINUOUS-WAVE AMPLIFIERS

(71) Applicant: MOTOROLA SOLUTIONS, INC., SCHAUMBURG, IL (US)

(72) Inventor: RODNEY W. HAGEN, LAKE IN THE HILLS, IL (US)

(21) Appl. No.: 14/495,033

(22) Filed: Sep. 24, 2014

(51) Int. Cl. H03F 1/02; H03F 3/19

(52) U.S. Cl. CPC H03F 1/0233; H03F 3/19; H03F 2200/451; H03F 2200/135

(57) ABSTRACT

Disclosed herein are methods and systems for efficient and adaptive operation of continuous-wave amplifiers. One embodiment takes the form of a method that includes adjusting an RF input power of an amplifier until an RF output power of the amplifier reaches a first target level. The method also includes adjusting a supply power of the amplifier until a power-added efficiency of the amplifier reaches a second target level.

### BACKGROUND OF THE INVENTION

In radio communications, it is important that radio transmissions are broadcast with sufficient transmit power to be received by other radios. As such, amplifiers are often used to provide additional power to various signals prior to transmission. The power amplifiers raise the power of a signal to be transmitted from a comparatively low power level to a higher power level sufficient for radio communications. Examples of commonly used devices that engage in radio transmissions include cell phones, smartphones, tablets, notebook computers, laptop computers, and the like, and further examples include the handheld transceiver, often referred to by terms such as walkie-talkie, two-way radio, mobile radio, and the like. And certainly many other example devices could be listed as well, as known to those having skill in the relevant art.

Power efficiency is also important in the context of radio transmissions, for at least the reason that improved efficiency results in less power used and lower operating costs for radio operators. However, ensuring a minimum transmit power at all times and striving for power efficiency are often seen in the art as being conflicting goals. Often it is the case that sustaining a minimum transmit power requires overpowering the system, while striving for power efficiency often results in not being able to sustain a given minimum transmit power. Accordingly, there is a need for methods and systems for efficient and adaptive operation of continuous-wave amplifiers.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 depicts a first example method, in accordance with an embodiment.

FIG. 2 depicts a second example method, in accordance with an embodiment.

FIG. 3 depicts a third example method, in accordance with an embodiment.

FIG. 4 depicts a first example transmitter circuit, in accordance with an embodiment.

FIG. 5 depicts a second example transmitter circuit, in accordance with an embodiment.

FIG. 6 depicts a third example transmitter circuit, in accordance with an embodiment.

FIG. 7 depicts a first graph, in accordance with an embodiment.

FIG. 8 depicts a second graph, in accordance with an embodiment.

FIG. 9 depicts a third graph, in accordance with an embodiment.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION OF THE INVENTION

Disclosed herein are methods and systems for efficient and adaptive operation of continuous-wave amplifiers. One embodiment takes the form of a method that includes adjusting an RF input power of an amplifier until an RF output power of the amplifier reaches a first target level. The method also includes adjusting a supply power of the amplifier until a power-added efficiency of the amplifier reaches a second target level. At least one embodiment involves carrying out these functions iteratively.

Another embodiment takes the form of a transmitter circuit that includes an amplifier having an RF input power, an RF output power, and a supply power. The system also includes a controller that is programmed to execute at least the functions described in the preceding paragraph. Moreover, any of the variations and permutations described in the ensuing paragraphs and anywhere else in this disclosure can be implemented with respect to any embodiments, including with respect to any method embodiments and with respect to any system embodiments.

In at least one embodiment, adjusting the RF input power of the amplifier involves adjusting an RF output power of a preamplifier, where the RF output power of the preamplifier drives the RF input power of the amplifier. In at least one such embodiment, the second target level is a maximum value at which the RF output power of the preamplifier does not exceed a third target level. In at least one other such embodiment, the preamplifier exhibits a substantially constant level of dissipation of energy when the RF output power of the preamplifier is within a steady-state operating range of the RF input power of the amplifier.

In at least one embodiment, the first target level is a sum of a third target level and a first loss level, where the third target level is associated with an interface that is joined to an RF output of the amplifier by a communication path that has a characteristic loss equal to the first loss level.

In at least one embodiment, adjusting the supply power of the amplifier involves adjusting a supply voltage of the amplifier.

In at least one embodiment, the following function is also carried out: calculating the power-added efficiency of the amplifier as the RF output power of the amplifier divided by the sum of the RF input power of the amplifier and the supply power of the amplifier.

In at least one embodiment, the second target level is a local maximum.

In at least one embodiment, the supply power of the amplifier is a common supply power for a system that includes a transmitter that includes the amplifier, and the following function is also carried out: detecting a transmit-standby power condition, and responsively reducing the supply power of the amplifier to a predetermined transmit-standby-mode level.

Before proceeding with this detailed description, it is noted that the entities, connections, arrangements, and the like that are depicted in—and described in connection with—the various figures are presented by way of example and not by way of limitation. As such, any and all statements or other indications as to what a particular figure “depicts,” what a particular element or entity in a particular figure “is” or “has,” and any and all similar statements—that may in isolation and out of context be read as absolute and therefore limiting—can only properly be read as being constructively preceded by a clause such as “In at least one embodiment, . . . .” And it is for reasons akin to brevity and clarity of presentation that this implied leading clause is not repeated ad nauseum in this detailed description.

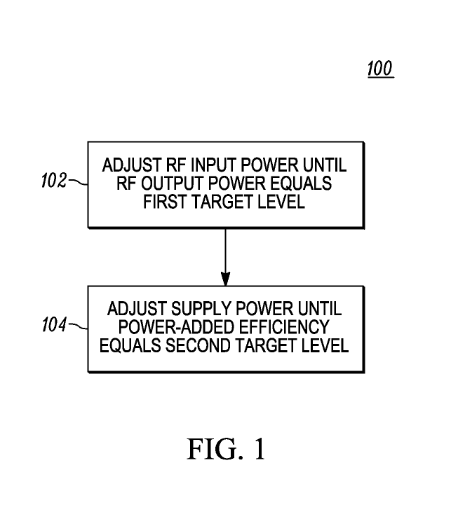

FIG. 1 depicts a first example method, in accordance with an embodiment. In particular, FIG. 1 depicts a method 100 that is described herein as being carried out by a transmitter circuit. This is by way of example and not limitation, as any circuit, device, and/or other system deemed by those of skill in the relevant art as being capable of and suitable for carrying out the described functions could certainly be used.

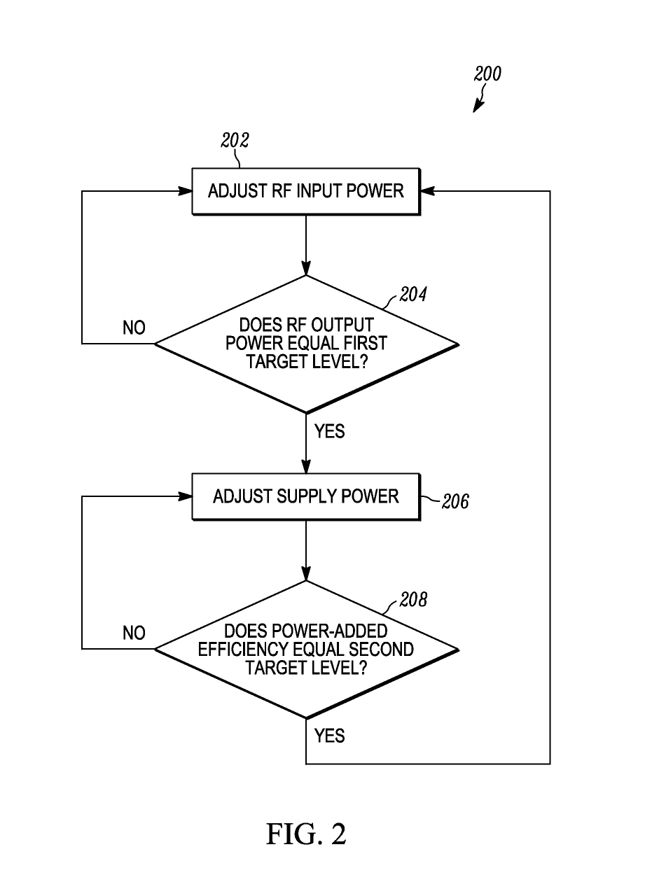

At step 102, the transmitter circuit adjusts the RF input power of an amplifier until the RF output power of the amplifier reaches a first target level. At step 104, the transmitter circuit adjusts the supply power of the amplifier until the power-added efficiency of the amplifier reaches a second target level. Although in the example method 100, step 102 is depicted and described as being carried out before step 104, this is by way of example of not limitation, as these steps could be carried out in the opposite order. Indeed, as described below in connection with FIG. 2, in some embodiments, these steps are carried out iteratively.

FIG. 2 depicts a second example method, in accordance with an embodiment. In particular, FIG. 2 depicts an example method 200 that, like the example method 100, is described herein by way of example as being carried out by a transmitter circuit.

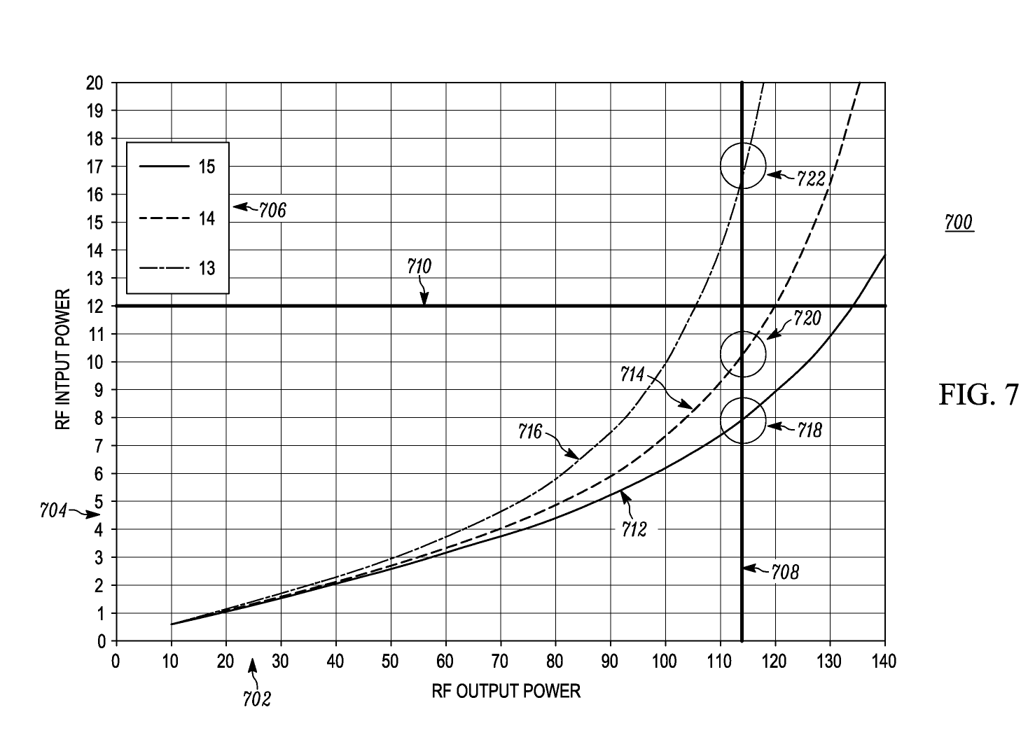

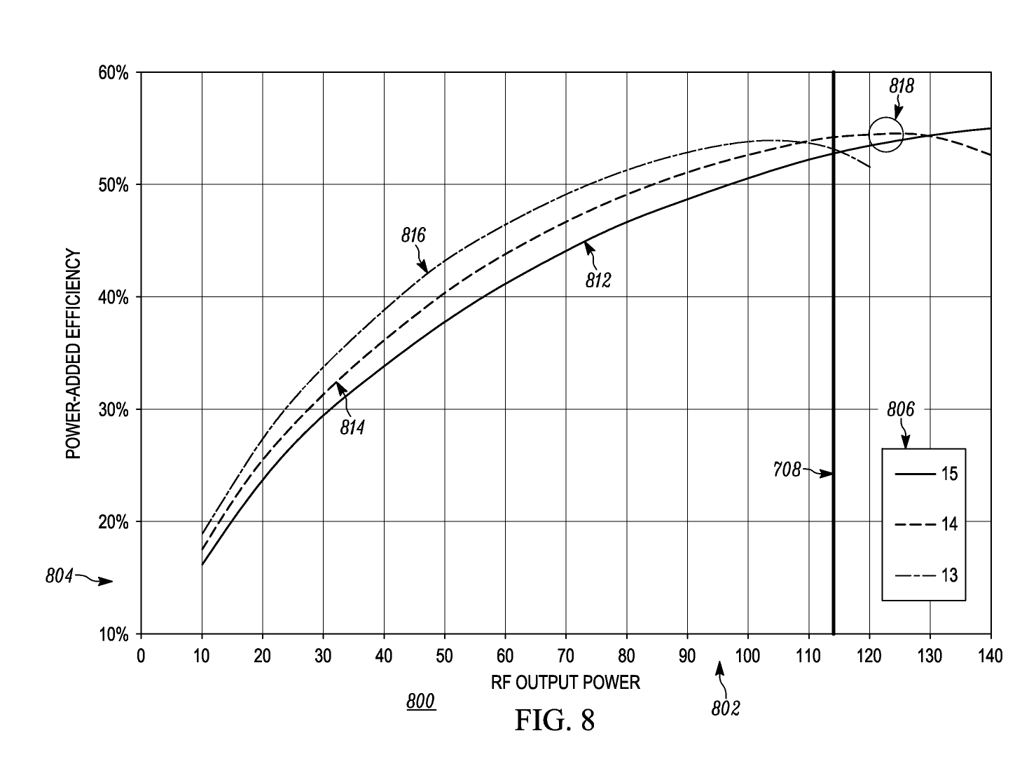

At step 202, the transmitter circuit adjusts the RF input power of an amplifier, and at step 204, the transmitter circuit determines whether the RF output power of the amplifier equals a first target level. The first target level is discussed more fully below in connection with FIGS. 7 and 8.

If the transmitter circuit determines at step 204 that the RF output power of the amplifier does not equal the first target level, processing returns to step 202. If, however, the transmitter circuit determines at step 204 that the RF output power of the amplifier does equal the first target level, processing proceeds to step 206, where the transmitter circuit adjusts the supply power of the amplifier, and then to step 208, where the transmitter circuit determines whether the power-added efficiency of the amplifier equals a second target level. The second target level is discussed more fully below in connection with FIG. 8, but in some cases the second target level may be a predetermined value, a local maximum, or any other value deemed by those having skill in the relevant art as being suitable for a given implementation or in a given context.

If the transmitter circuit determines at step 208 that the power-added efficiency of the amplifier does not equal the second target level, processing returns to step 206. If, however, the transmitter circuit determines at step 208 that the power-added efficiency of the amplifier does equal the second target level, processing returns to step 202. As such, it can be appreciated that the example method 200 involves an iterative execution of the respective steps of the example method 100.

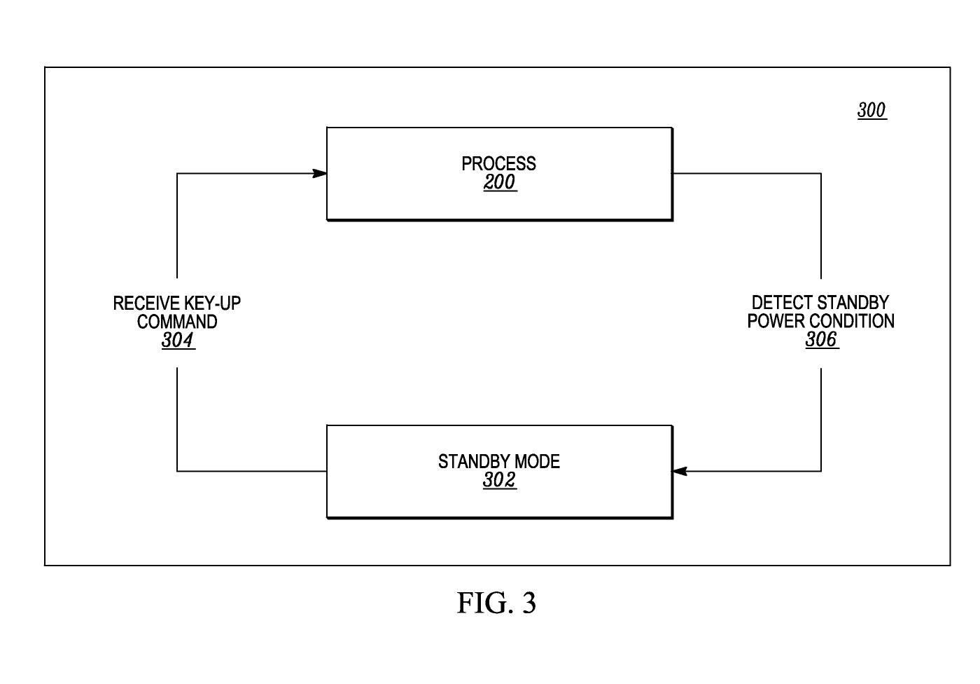

In some embodiments, a method such as the example method 100 or the example method 200 is carried out as a sub-method or sub-process of another method. One such example is described below in connection with FIG. 3.

FIG. 3 depicts a third example method, in accordance with an embodiment. In particular, FIG. 3 depicts an example method 300 that is described herein by way of example as being carried out by a system (e.g., a base station) that includes a transmitter that itself includes a transmitter circuit having an amplifier. In other embodiments, the method 300 is carried out by a transmitter circuit; and certainly other examples are possible as well. As can be seen in FIG. 3, as part of carrying out the method 300, the system carries out, at different times, the above-described method (i.e., process) 200 and a standby (e.g., low-power, non-transmitting, and/or the like) mode 302.

When the system is in the standby mode 302 and then receives a key-up command (as shown at 304), the system responsively transitions into performing the method 200. This transition may involve raising the voltage potential of the supply power of the amplifier. As examples, the system could receive key-up power commands via a user interface, from one or more other devices and/or systems, and/or from one or more other sources deemed suitable by those having skill in the relevant art.

When the system is performing the method 200 and then detects a standby power condition (as shown at 306), the system responsively transitions into the standby mode 302. In an embodiment, the supply power of the amplifier is a common supply power for the system, and entering and/or remaining in the standby mode 302 involves reducing the voltage potential of the supply power of the amplifier to a predetermined transmit-standby-mode level, with the aim of minimizing the power consumption of the transmitter circuit. As examples, the detected standby power condition could be that one or more signals (e.g., the RF input power) and/or one or more status indicators have been in a low-power or other similar inactive state for at least a certain amount of time. And certainly other examples of standby power conditions could be listed here.

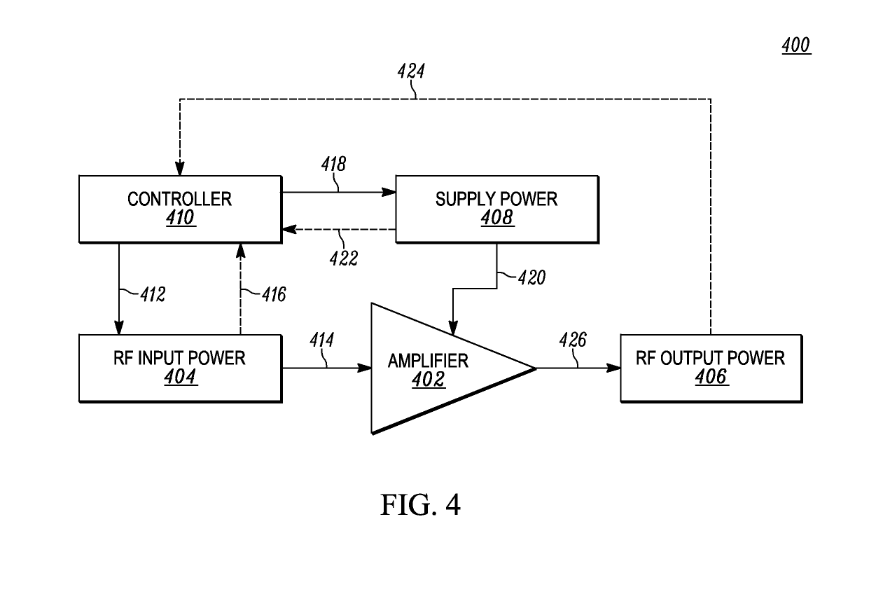

The example methods described above in connection with FIGS. 1-3 are described herein by way of example as being carried out by transmitter circuits (and/or by systems that include transmitter circuits), three examples of which are described below in connection with FIGS. 4-6.

FIG. 4 depicts a first example transmitter circuit, in accordance with an embodiment. In particular, FIG. 4 depicts an example transmitter circuit 400 as including an amplifier 402 that has an RF input power 404, an RF output power 406, and a supply power 408. The transmitter circuit 400 also includes a controller 410 that is programmed to execute a set of functions that may include the method 100 and/or the method 200, as examples. In different embodiments, the various components that are depicted in this and other examples are connected via circuitry and/or other components deemed suitable by those having skill in the relevant art for a given implementation or in a given context, though for brevity and clarity, and not by way of limitation, such circuitry and/or other components are not depicted in this disclosure.

In some embodiments, the RF output power 406 of the amplifier 402 is measured directly at the output of the amplifier. However, the RF output power 406 of the amplifier 402 can also or instead be measured at any other point (e.g., interface) in a communication path that extends from the output of the amplifier.

Example transmitter circuit 400 can be used to execute the method 100 and/or the method 200. The controller 410 adjusts the RF input power 404 of the amplifier 402 via a control signal 412. The controller 410 detects the RF output power 406 of the amplifier 402 via a feedback signal 424, and stops adjusting the RF input power 404 of the amplifier 402 when the RF output power 406 of the amplifier 402 is equal to a first target level. These functions correspond to step 102 of the method 100 and to steps 202 and 204 of the method 200. Moreover, it is noted that, in the example transmitter circuit 400 that is depicted in FIG. 4, the RF input power 404 of the amplifier 402 is conveyed to the amplifier 402 as depicted at signal 414, and the RF output power 406 of the amplifier 402 is conveyed from the amplifier 402 as depicted at signal 426.

The controller 410 adjusts the supply power 408 of the amplifier 402 via a control signal 418, which supply power 408 is provided to amplifier 402 via signal 420. The controller 410 receives the feedback signals 416, 422, and 424, and calculates the power-added efficiency of the amplifier 402. The feedback signal 416 conveys to the controller 410 the RF input power 404 of the amplifier 402. The feedback signal 422 conveys to the controller 410 the supply power 408 of the amplifier 402. And, as noted above, the feedback signal 424 conveys to the controller 410 the RF output power 406 of the amplifier 402. When the power-added efficiency of the amplifier 402 equals the second target level, the controller 410 stops adjusting the supply power 408 of the amplifier 402. These functions correspond to step 104 of the method 100 and to steps 206 and 208 of the method 200.

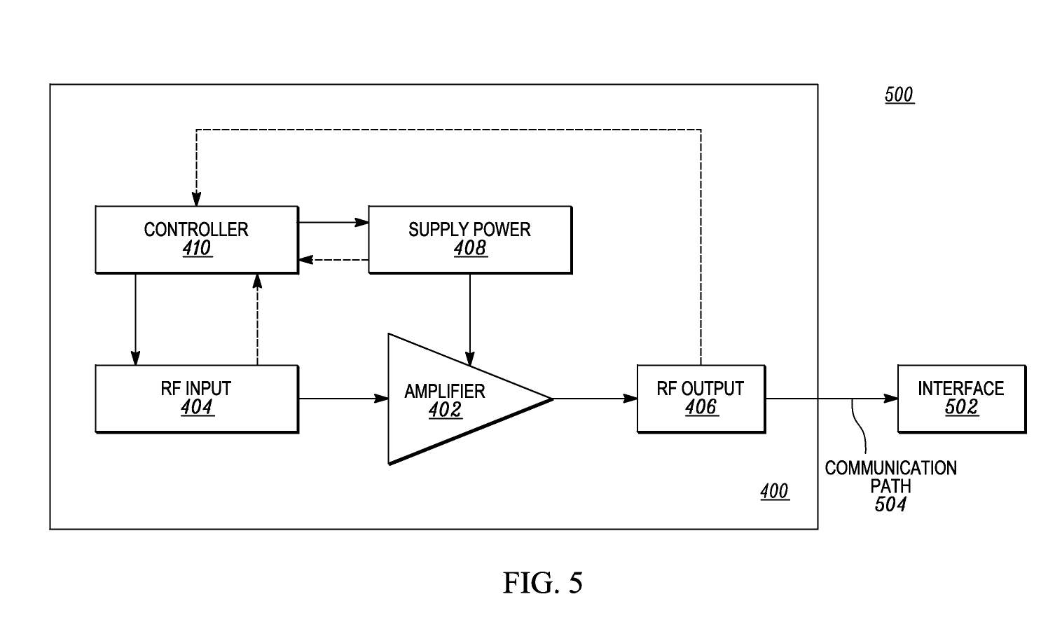

FIG. 5 depicts a second example transmitter circuit, in accordance with an embodiment. In particular, FIG. 5 depicts an example transmitter circuit 500 as including the components of the transmitter circuit 400 of FIG. 4, as well as an interface 502 and a communication path 504, which extends between the RF output 406 of the amplifier 402 and the interface 502. The communication path 504 exhibits a characteristic loss equal to what is referred to herein as a first loss level.

As described herein, various embodiments involve adjusting the RF input power of an amplifier until the RF output power of that amplifier reaches what is referred to herein as a first target level. In various different instances, this first target level could be based on one or more customer requirements, one or more government regulations, one or more engineering considerations, and/or the like. Thus, as an example, a customer may require that the RF output power 406 be equal (or substantially equal) to 100 watts (100 W); in such an example, in the parlance of this disclosure, the first target level would be 100 W. As another example, a customer may require that the output power—as measured at the interface 502—be equal to 100 W; in that instance, and assuming an example loss level of 13 W between the RF output 406 and the interface 502 along the communication path 504, then, in the parlance of this disclosure, the first target level (for the RF output power 406) would be 113 W, computed as the sum of (i) the power requirement (100 W) at the interface 502 and (ii) the characteristic loss (13 W) along the communication path 504 between the RF output power 406 and the interface 502. And certainly numerous other examples could be listed as well.

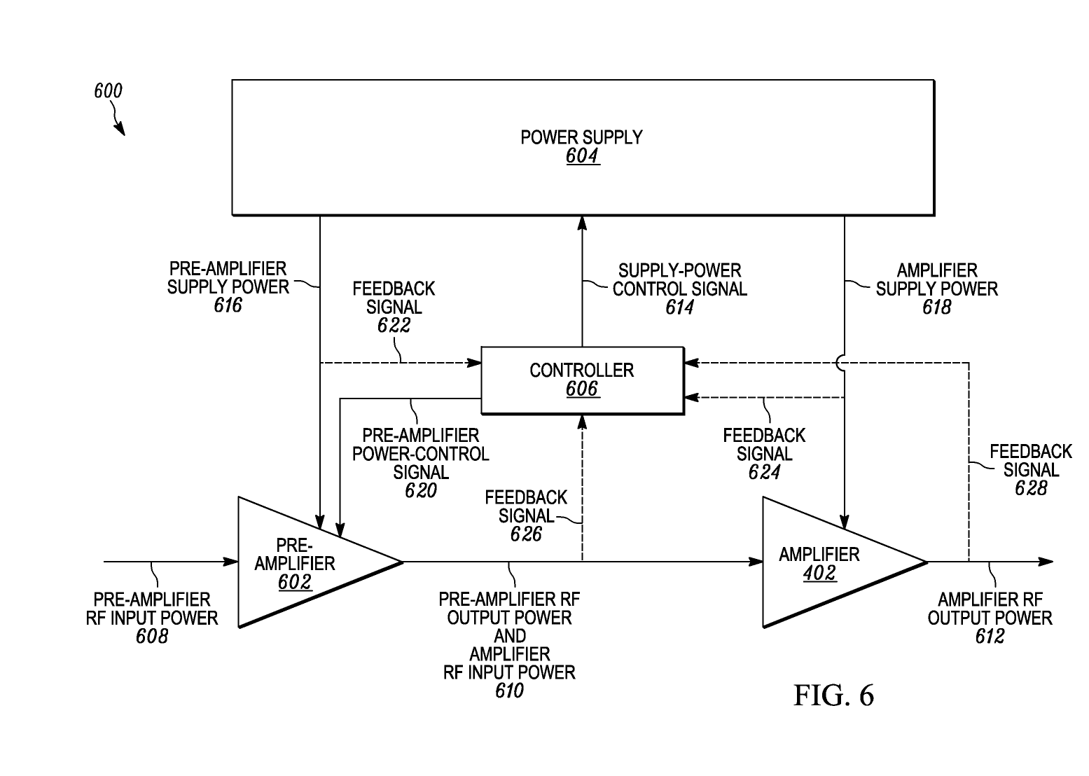

FIG. 6 depicts a third example transmitter circuit, in accordance with an embodiment. In particular, FIG. 6 depicts an example transmitter circuit 600 as including the amplifier 402, a preamplifier 602, a power supply 604, and a controller 606. It is explicitly noted and pointed out here that, in the depicted embodiment, the signal 610 is both (i) the RF output power of the preamplifier 602 and (ii) the RF input power to the amplifier 402; that is, the RF output power of the preamplifier 602 drives the RF input power of the amplifier 402; as such, in this description of FIG. 6, the RF power 610 is referred to at different times as “the RF output power 610 of the preamplifier 602” and “the RF input power 610 of the amplifier 402.”

In the depicted example, the controller 606 outputs two control signals 614 and 620, and receives four feedback signals 622-628. These six signals are described over the next two paragraphs.

The first of the two control signals is the supply-power control signal 614, which the controller 606 transmits to the power supply 604, which responsively transmits (i) a preamplifier supply power 616 to the preamplifier 602 and (ii) an amplifier supply power 618 to the amplifier 402. It is explicitly noted that, in some embodiments, the preamplifier supply power 616 is equal to the amplifier supply power 618, and in some embodiments the preamplifier supply power 616 is not equal to the amplifier supply power 618. That is to say, the preamplifier supply power 616 and the amplifier supply power 618 may or may not be conveying power at the same delivery voltage. The second of the two control signals is a preamplifier power-control signal 620, which the controller 606 transmits to the preamplifier 602.

The first of the four feedback signals is a feedback signal 622, by which the controller 606 monitors the preamplifier supply power 616. The second of the four feedback signals is a feedback signal 624, by which the controller 606 monitors the amplifier supply power signal 618. The third of the four feedback signals is a feedback signal 626, by which the controller 606 monitors the RF output power 610 of the preamplifier 602 and the RF input power 610 of the amplifier 402 (i.e., the RF power 610). The fourth of the four feedback signals is a feedback signal 628, by which the controller 606 monitors the RF output power 612 of the amplifier 402.

In the example transmitter circuit 600, the controller 606 is programmed to execute a set of functions that may include the method 100 and/or the method 200, as examples. The ensuing paragraphs provide example implementations of the controller 606 carrying out some such functions.

This paragraph describes an example implementation according to which the controller 606 adjusts the RF input power 610 of the amplifier 402 until the RF output power 612 of the amplifier 402 reaches the first target level, corresponding to step 102 of the method 100 and to steps 202 and 204 of the method 200. The controller 606 uses the preamplifier control signal 620 to adjust the RF output power 610 of the preamplifier 602; and it is noted that the preamplifier RF input power 608 would typically also be a determinative input with respect to the RF output power 610 of the preamplifier 602; it may well be the case, however, that the controller 606 cannot influence the value of the RF signal 608. In the depicted example, when the feedback signal 628 indicates that the RF output power 612 of the amplifier 402 is equal to (or substantially equal to, i.e., within a tolerance of) the first target level, the controller 606 stops adjusting the RF input power 610 of the preamplifier 602 by way of the control signal 620.

This paragraph describes an example implementation according to which the controller adjusts the supply power 618 of the amplifier 402 until the power-added efficiency of the amplifier 402 reaches the second target level, corresponding to step 104 of the method 100 and to steps 206 and 208 of the method 200. The controller 606 uses the supply-power control signal 614 to adjust the supply power 618 of the amplifier 402 by way of the variable power supply 604. In the depicted embodiment, the controller 606 calculates the power-added efficiency of the amplifier 402 as (i) the RF output power 612 of the amplifier 402 (by way of the feedback signal 628) divided by (ii) the sum of (a) the RF input power 610 of the amplifier 402 (by way of the feedback signal 626) and (b) the supply power 618 (by way of the feedback signal 624). This calculation is given by the following equation:

$$PAE = \frac{{RF}_{OUT}}{( {RF}_{IN} + {P}_{SUPPLY} )} \qquad ( Equation 1 )$$

Where RF_{OUT} is the RF output power 612 of the amplifier 402, RF_{IN} is the RF input power 610 of the amplifier 402, and P_{SUPPLY} is the supply power 618 of the amplifier 402. In the depicted example, when the controller 606 determines that the power-added efficiency of the amplifier 402 is equal to (or substantially equal to, i.e., within a tolerance of) the second target level, the controller 606 stops using the supply-power control signal 614 to adjust the supply power 618 of the amplifier 402.

In at least one embodiment, the controller 606 estimates the power-added efficiency of the amplifier 402 on more of a system-wide level by simply dividing (i) the output power level of the transmitted signal (e.g., the RF output power 612 of the amplifier 402) by (ii) the total amount of power consumed by the system; when considering the fact that the amplifier 402 would often be the system component that (often by a wide margin) consumes more power than any other component, the power-added efficiency of the system as a whole may be considered a reasonable proxy for the power-added efficiency of the amplifier 402. And certainly other metrics and/or equations for calculating and/or estimating the power-added efficiency of the amplifier 402 could be listed here, as known to those having skill in the relevant art.

Three example methods are described above in connection with FIGS. 1-3, and three example transmitter circuits—programmed to execute one or more of those methods—are described above in connection with FIGS. 4-6. Below, in connection with FIGS. 7-9, three example graphs are presented and discussed. These example graphs provide examples in connection with, and illustrate concepts pertinent to, the present methods and systems, including embodiments described above in connection with FIGS. 1-6. These graphs provide illustrative implementations and example values with respect to terms used above such as first target level, second target level, and the like. And it is noted that, by way of example and not limitation, these graphs are described below in a manner that, for better illustration, makes reference to the elements of the example transmitter circuit 600 of FIG. 6.

FIG. 7 depicts a first graph, in accordance with an embodiment. In particular, FIG. 7 depicts a graph 700 that has a horizontal axis 702, a vertical axis 704, and a legend 706. The horizontal axis 702 corresponds, in increasing order from left to right, to the RF output power 612 of the amplifier 402; the horizontal axis 702 is visually divided every ten watts. The vertical axis 704 corresponds, in increasing order from bottom to top, to the RF input power 610 of the amplifier 402; the vertical axis 704 is visually divided every one watt. The legend 706 depicts three example supply voltages (i.e., supply powers 618) of the amplifier 402.

The graph 700 also includes three example curves 712, 714, and 716. When viewed in connection with the legend 706, it can be appreciated that the curve 712 corresponds to a supply voltage of 15V, the curve 714 corresponds to a supply voltage of 14V, and the curve 716 corresponds with a supply voltage of 13V. And while the example graph 700 depicts three example supply voltages for the amplifier 402, those having skill in the relevant art will readily appreciate that numerous non-integer supply voltages could be depicted in the graph 700 and used in the transmitter circuit 600, and that the three depicted curves 712, 714, and 716 are provided for illustration.

The graph 700 also includes a vertical line 708 and a horizontal line 710. The vertical line 708 is at approximately 113 W, consistent with an example described above in connection with FIG. 5. The vertical line 708 corresponds to what is referred to in this disclosure as the first target level; that is, the vertical line 708 corresponds to the target value for the RF output power 612 of the amplifier 402. The horizontal line 710 is at approximately 12 W, and corresponds to an upper (i.e., not-to-exceed) limit that could be present in certain contexts with respect to the RF output power 610 of the preamplifier 602 (and equivalently, then, an upper (i.e., not-to-exceed) limit with respect to the RF input power 610 of the amplifier 402). Among other examples, the horizontal line 710 could represent a maximum RF output power 610 that the preamplifier 602 is physically able to attain, or may instead represent a maximum RF output power 610 that the preamplifier can attain based on the range of RF input powers 608 that are recommended and/or possible to use with respect to the preamplifier 602.

In any event, then, it will be appreciated by those of skill in the relevant art that, with respect to the amplifier 402 in this example, a given supply voltage (i.e., supply power 618) is a viable option only if its corresponding curve crosses the vertical line 708 below the horizontal line 710; to wit, a given supply voltage is a viable option if and only if the required RF output power 612 of the amplifier 402 can be attained without exceeding the upper bound on the RF input power 610 of the amplifier 402 (which may in actuality reflect an upper bound on the RF input power 608 of the preamplifier 602).

The 15V curve 712 crosses the vertical line 708 at a point 718, below the horizontal line 710. Similarly, the 14V curve 714 crosses the vertical line 708 at a point 720, also below the horizontal line 710. The 13V curve 716, however, crosses the vertical line 708 at a point 722 that is above the horizontal line 722. Thus, the graph 700 indicates that 13V would be too low of a supply voltage (i.e., a supply power 618) for the amplifier 402. The graph 700 further indicates that the supply voltage that could attain the target RF output power (i.e., the vertical line 708) while running the RF input power 610 of the amplifier 402 (i.e., the RF output power 610 of the preamplifier 602) closest to its operating limit would be a supply voltage falling in the range between the 13V to which the curve 716 corresponds and the 14V to which the curve 714 corresponds. If a given implementation provided only the integer values of 13V, 14V, and 15V as options for the supply voltage, the graph 700 indicates that 14V and 15V are viable options, while 13V is not a viable option.

Moreover, as is further explained below, the three curves on the graph 800 of FIG. 8 correspond to the same three supply voltages as the three curves on the graph 700 of FIG. 7. And similar line styles are used for the curves in these two graphs as well.

FIG. 8 depicts a second graph, in accordance with an embodiment. In particular, FIG. 8 depicts a graph 800 that has a horizontal axis 802, a vertical axis 804, and a legend 806. The horizontal axis 802 is the same as the horizontal axis 702 of the graph 700. The vertical axis 804 corresponds, in increasing order from bottom to top, to the power-added efficiency of the amplifier 402; the vertical axis 804 is visually divided every ten percent. The legend 806 is the same as the legend 706. Moreover, the vertical line 708 from the graph 700 is also depicted in the graph 800.

Similar to the graph 700, the graph 800 includes three example curves 812, 814, and 816. When viewed in connection with the legend 806, it can be appreciated that (i) like the curve 712, the curve 812 corresponds to a supply voltage of 15V; (ii) like the curve 714, the curve 814 corresponds to a supply voltage of 14V; and (iii) like the curve 716, the curve 816 corresponds with a supply voltage of 13V. As was stated above in connection with the graph 700, those having skill in the relevant art will readily appreciate that numerous non-integer supply voltages could be depicted in the graph 800 and used in the transmitter circuit 600, and that the three depicted curves 812, 814, and 816 are provided for illustration.

Moreover, with respect to each of the curves 812, 814, and 816, as RF output power 612 of the amplifier 402 increases, the power-added efficiency of the amplifier 402 increases until reaching a local maximum at a certain point, and then begins to decrease. It can be seen in the graph 800 that (i) the 13V curve 816 reaches a local maximum of approximately 54% power-added efficiency at an RF output power of approximately 103 W; (ii) the 14V curve 814 reaches a local maximum of approximately 55% power-added efficiency at an RF output power of approximately 124 W (at a point that is labeled 818 in the graph 800); and (iii) the 15V curve does not reach a local maximum level of power-added efficiency within the range of RF-output-power values that are depicted on the horizontal axis 802 of the graph 800.

The above description of FIG. 7 establishes that, if a given implementation (in which the horizontal line 710 of the graph 700 was an operating constraint) provided only the integer values of 13V, 14V, and 15V as options for the supply voltage: (i) only two of these would be viable options: (a) 14V (corresponding to the curves 714 and 814) and (b) 15V (corresponding to the curves 712 and 812), while (ii) 13V (corresponding to the curves 716 and 816) is not a viable option. The graph 800 of FIG. 8 depicts that, in such an implementation, the present methods and systems would operate to select 14V as the operating supply voltage for the amplifier 402: as between 14V and 15V, the curve 814 reaches a local maximum (at point 818) closer to the vertical line 708 (i.e., closer to the steady-state operating RF output power 612 of the amplifier 402.

In an implementation in which more granular supply voltages are possible, the present methods and systems would arrive at a steady-state operating supply voltage (i.e., supply power 618) for the amplifier 402 of a value between 13V and 14V. In particular, the steady-state operating voltage for the amplifier 402 at which the present methods and systems would operate to arrive—i.e., that the present methods and systems would dynamically seek out—would be a supply voltage (i) whose corresponding curve on the graph 700 would cross the vertical line 708 below (or perhaps right at) the horizontal line 710 (i.e., that could achieve the required RF output power 612 of the amplifier 402 within the operating range of the preamplifier 602) and (ii) whose corresponding curve on the graph 800 would reach a local maximum right on the vertical line 708 (i.e., that maximized the power-added efficiency of the amplifier 402 (and thus approached a maximization of the power-added efficiency of the system as a whole, for reasons described above) right at the steady-state (and requirement-meeting) RF output power 612 of the amplifier 402.

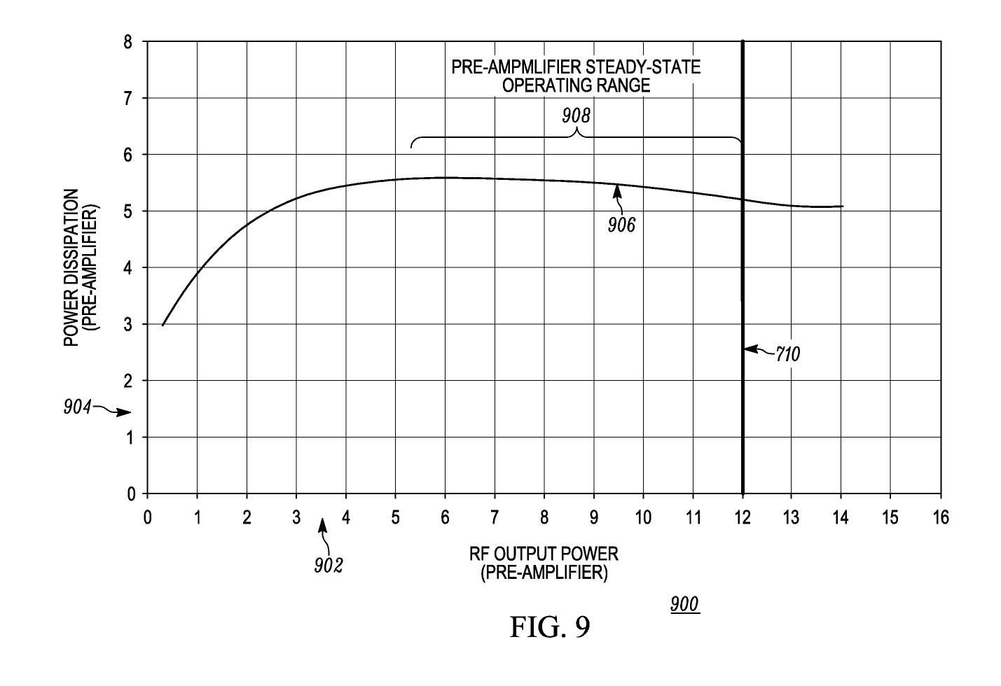

FIG. 9 depicts a third graph, in accordance with an embodiment. In particular, FIG. 9 depicts a graph 900 that has a horizontal axis 902 and a vertical axis 904. The horizontal axis 902 corresponds, in increasing order from left to right, to the RF output power 610 of the preamplifier 602; the horizontal axis 902 is visually divided every one watt. The vertical axis 904 corresponds, in increasing order from bottom to top, to the amount of power dissipated by the preamplifier 602; the vertical axis 904 is visually divided every one watt. The graph 900 includes a single curve 906 that corresponds to a given supply power 616 of the preamplifier 602. The graph 900 includes a brace that depicts the steady-state operating range (with respect to the RF output power 610) of the preamplifier 602. The vertical line 710 represents the same upper limit on the RF output power 610 of the preamplifier 602 that the horizontal line 710 represents in FIG. 7.

It can be seen in the graph 900 that, in the depicted example, the preamplifier 602 exhibits a substantially constant level (of about 5.3-5.5 W) of dissipation of energy when the RF output power 610 of the preamplifier 602 is within the steady state operating range 908 of the RF input power 608 of the preamplifier 602. When such is the case, it illustrates that the power-added efficiency of the amplifier 402 is an excellent proxy for the power-added efficiency of the transmitter circuit 602 as a whole, since none of the operating values of the transmitter circuit make much difference with respect to the power-added efficiency of the preamplifier 602. Thus, when endeavoring to maximize the power-added efficiency of the preamplifier 602 and the amplifier 402 as a combined system, it is enough to maximize the power-added efficiency of the amplifier 402. And it is explicitly noted that, although the graph 900 depicts only a single curve (i.e., the curve 906) that corresponds to a given supply power 616 of the preamplifier 602, this is for clarity of presentation, and is by way of example and not limitation. Indeed, any number (i.e., a family) of curves could be depicted in FIG. 9, illustrating that, in some embodiments, the pre-amplifier 602, if supplied via a variable supply power, has a substantially flat dissipation response at a number of different supply powers 616 when the RF output power 610 of the preamplifier 602 is within the steady state operating range 908 of the RF input power 608 of the preamplifier 602.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing,” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element preceded by “comprises . . . a,” “has . . . a,” “includes . . . a,” “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially,” “essentially,” “approximately,” “about,” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A method including:
adjusting an RF input power of an amplifier until an RF output power of the amplifier reaches a first target level; and
adjusting a supply power of the amplifier until a power-added efficiency of the amplifier reaches a second target level.

2. The method of claim 1, further including iteratively:
adjusting the RF input power of the amplifier until the RF output power of the amplifier reaches the first target level; and
adjusting the supply power of the amplifier until the power-added efficiency of the amplifier reaches the second target level.

3. The method of claim 1, wherein adjusting the RF input power of the amplifier involves adjusting an RF output power of a preamplifier, the RF output power of the preamplifier driving the RF input power of the amplifier.

4. The method of claim 3, wherein the second target level is a maximum value at which the RF output power of the preamplifier does not exceed a third target level.

5. The method of claim 3, wherein the preamplifier exhibits a substantially constant level of dissipation of energy when the RF output power of the preamplifier is within a steady-state operating range of the RF input power of the amplifier.

6. The method of claim 1, wherein the first target level is a sum of a third target level and a first loss level, the third target level being associated with an interface that is joined to an RF output of the amplifier by a communication path having a characteristic loss equal to the first loss level.

7. The method of claim 1, wherein adjusting the supply power of the amplifier involves adjusting a supply voltage of the amplifier.

8. The method of claim 1, further including calculating the power-added efficiency of the amplifier as the RF output power of the amplifier divided by the sum of the RF input power of the amplifier and the supply power of the amplifier.

9. The method of claim 1, wherein the second target level is a local maximum.

10. The method of claim 1, wherein the supply power of the amplifier is a common supply power for a system that includes a transmitter that includes the amplifier, the method further including:
detecting a transmit-standby power condition, and responsively reducing the supply power of the amplifier to a predetermined transmit-standby-mode level.

11. A transmitter circuit including:
an amplifier having an RF input power, an RF output power, and a supply power; and
a controller programmed to execute the following functions:
adjusting the RF input power of the amplifier until the RF output power of the amplifier reaches a first target level; and
adjusting the supply power of the amplifier until a power-added efficiency of the amplifier reaches a second target level.

12. The transmitter circuit of claim 11, wherein the controller being programmed to execute includes the controller being programmed to iteratively execute.

13. The transmitter circuit of claim 11, further including a preamplifier, wherein adjusting the RF input power of the amplifier involves adjusting an RF output power of the preamplifier, the RF output power of the preamplifier driving the RF input power of the amplifier.

14. The transmitter circuit of claim 13, wherein the second target level is a maximum value at which the RF output power of the preamplifier does not exceed a third target level.

15. The transmitter circuit of claim 13, wherein the preamplifier exhibits a substantially constant level of dissipation of energy when the RF output power of the preamplifier is within a steady-state operating range of the RF input power of the amplifier.

16. The transmitter circuit of claim 11, wherein the first target level is a sum of a third target level and a first loss level, the third target level being associated with an interface that is joined to an RF output of the amplifier by a communication path having a characteristic loss equal to the first loss level.

17. The transmitter circuit of claim 11, wherein adjusting the supply power of the amplifier involves adjusting a supply voltage of the amplifier.

18. The transmitter circuit of claim 11, wherein the controller is further programmed to execute the following function:
calculating the power-added efficiency of the amplifier as the RF output power of the amplifier divided by the sum of the RF input power of the amplifier and the supply power of the amplifier.

19. The transmitter circuit of claim 11, wherein the second target level is a local maximum.

20. The transmitter circuit of claim 11, wherein the supply power of the amplifier is a common supply power for a system that includes the transmitter circuit, wherein the controller is further programmed to execute the following function:
detecting a transmit-standby power condition, and responsively reducing the supply power of the amplifier to a predetermined transmit-standby-mode level.
